(19) United States
(12) Patent Application Publication
(10) Pub. No.: US 2026/0122983 A1
(43) Pub. Date: Apr. 30, 2026

(54) MOSFET WITH LOWER DOPANT CONCENTRATION WELL SECTION AND RADIATION-HARDENING AGAINST SEGR EFFECT

(71) Applicant: Microchip Technology Incorporated, Chandler, AZ (US)

(72) Inventors: Shesh Mani Pandey, Gilbert, AZ (US); Joseph Terence Smith, Tempe, AZ (US)

(73) Assignee: Microchip Technology Incorporated, Chandler, AZ (US)

(21) Appl. No.: 19/367,589

(22) Filed: Oct. 23, 2025

Related U.S. Application Data
(60) Provisional application No. 63/711,552, filed on Oct. 24, 2024.

(51) Int. Cl. H10D 62/10; H10D 30/01; H10D 30/66; H10D 62/832

(52) U.S. Cl. CPC H10D 62/109; H10D 30/0291; H10D 30/66; H10D 62/8325

(57) ABSTRACT

A power metal oxide semiconductor field-effect transistor is radiation-hardened against a single-event gate rupture effect, and a method of making such a transistor is disclosed. A volume of semiconductor material includes first and second sides and a centrally located junction field effect transistor neck region. The metal oxide semiconductor field-effect transistor includes a source, a well located between the source and the JFET neck region, and a dielectric material. The well includes a first well portion and a second well portion. The second well portion is located between the first well portion and the JFET neck region and has a lower dopant concentration than the first well portion. The dielectric material overlies the first well portion, at least part of the second well portion, and at least part of the source. The dielectric material presents a thicker dielectric portion located over the second well portion.

### RELATED APPLICATION

The present U.S. non-provisional patent application is related to and claims priority benefit of an earlier-filed U.S. provisional patent application titled "SiC Power MOSFET with Split Gate and Radiation-Hardened Against SEGR Effect," Serial No. 63/711,552, filed October 24, 2024. The entire content of the identified earlier-filed application is incorporated by reference as if fully set forth herein.

### FIELD

The present disclosure relates to metal oxide semiconductor field-effect transistors and methods of making them, and more particularly, the various examples described herein concern a power metal oxide semiconductor field-effect transistor with radiation-hardening against a single-event gate rupture effect, and a method of making a power metal oxide semiconductor field-effect transistor with radiation-hardening against a single-event gate rupture effect.

### BACKGROUND

A metal-oxide-semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide a power MOSFET with radiation-hardening against a single-event gate rupture (SEGR) effect, and a method of making a power MOSFET with radiation-hardening against a SEGR effect. Broadly, examples are suitable for applications in environments (e.g., space or military) in which radiation exposure could otherwise significantly degrade the performance or even catastrophically damage non-hardened devices. Further, examples improve the SEGR radiation hardness of the power MOSFET without significantly degrading the drain-source "on" resistance (Rdson).

In an example, a metal oxide semiconductor field-effect transistor (MOSFET) may include a volume of semiconductor material including a first end, a second end, a first side, and a second side. The MOSFET may also include a junction field-effect JFET neck region located between the first side and the second side of the volume of semiconductor material. The MOSFET may also include a source and a well. The well may be located between the source and the JFET neck region. The well may include a first well portion and a second well portion. The second well portion may be located between the first well portion and the JFET neck region and may have a lower dopant concentration than the first well portion. The MOSFET may further include a dielectric material overlying the first well portion, at least part of the second well portion, and at least part of the source. The dielectric material may present a thicker dielectric portion located over the second well portion. The preceding example may further include any one or more of the following features. The dielectric material may include a first dielectric layer overlying the first end of the volume of semiconductor material along the first well portion, at least part of the second well portion, and at least part of the source. The dielectric material may include a second dielectric layer overlying the first dielectric layer along at least part of the second well portion such that the first and second dielectric layers cooperatively present the thicker dielectric portion. The first dielectric layer may be relatively thinner than the second dielectric layer. The first layer of dielectric material may be between fifty (50) and one hundred (100) nanometers in thickness, and the second layer of dielectric material may be between one hundred fifty (150) and three hundred (300) nanometers in thickness. The thicker dielectric portion may extend along part but not all of the second well portion. The second well portion may present a length defined along the first end of the volume of semiconductor material, and the thicker dielectric portion may extend along more than half the length of the second well portion. The thicker dielectric portion may extend along part but not all of the JFET neck region. The thicker dielectric portion may not extend over the first well portion or the source. The well may include spaced apart well sections, each including respective first and second well portions, the JFET neck region may be located between the second well portions of the spaced apart well sections, and the source may include spaced apart source sections, each being located between one of the well sections and a respective one of the sides of the volume of semiconductor material. The dielectric material may overlie each of the first well portions, at least part of each of the second well portions, and at least part of each of the source sections. The thicker dielectric portion may be located along part but not all of each of the second well portions. The JFET neck region may present a central JFET neck portion spaced between the second well portions of the spaced apart well sections, and the thicker dielectric portion may extend over the JFET neck region adjacent each of the second well portions but not over the central JFET neck portion. The MOSFET may further include a gate structure located over the dielectric material. The dielectric material and the gate structure may not extend over the central JFET neck portion. The MOSFET may further include a layer of borophosphosilicate glass (BPSG) at least over the gate structure and the JFET neck region, including over the central JFET neck portion. The dielectric material and the gate structure may extend over only part of the JFET neck region.

The volume of semiconductor material may include an N-type epitaxial semiconductor material. The MOSFET may include a first source section including a first N+ material located above and adjacent to a first well section, a first body section including a first P+ material located adjacent to the first source section opposite the first well section, a first drain section including an N+ substrate material located at the second end of the volume of semiconductor material, and a first channel through the volume of semiconductor material between the first source section and the first drain section. The foregoing may be considered a first transistor side located at the first side of the volume of semiconductor material, and the MOSFET may further include a second transistor side located at the second side of the volume of semiconductor material, with the JFET neck region being located between the first and second transistor sides. The second transistor side may include a second well section, a second source section including a second N+ material located above and adjacent to the second well section, a second body section including a second P+ material located adjacent to the second source section opposite the second well section, a second drain section including an N+ substrate material located at the second end of the volume of semiconductor material, and a second channel through the volume of semiconductor between the second source section and the second drain section. The gate structure and the dielectric material may not be over the center portion of the JFET neck region.

In another example, a method of making a metal oxide semiconductor field-effect transistor (MOSFET) may include the following steps. A volume of semiconductor material may be grown, the volume of semiconductor material including a first end, a second end, a first side, and a second side, and further including a JFET neck region between the first side and the second sides. A source may be provided. A well may be provided between the source and the JFET neck region. The step of providing the well may include providing a first well portion adjacent the source and a second well portion, having a lower dopant concentration than the first well portion, between the first well portion and the JFET neck region. The method may further include the step of providing a dielectric material over the first well portion, at least part of the second well portion, and at least part of the source. The step of providing the dielectric material may include forming the dielectric material to have a thicker portion over the second well portion.

The preceding example may further include any one or more of the following features. The step of providing the dielectric material may include forming a first dielectric layer and a relatively thicker second dielectric layer. The step of forming the first dielectric layer may include extending the first dielectric layer over the first end of the volume of semiconductor material along the first well portion, at least part of the second well portion, and at least part of the source. The step of forming the second dielectric layer may include extending the second dielectric layer over the first dielectric layer along at least part of the second well portion such that the first and second dielectric layers cooperatively present the thicker dielectric portion. The step of forming the first and second dielectric layers may be performed such that the first dielectric layer is between fifty (50) and one hundred (100) nanometers in thickness, and the second dielectric layer is between one hundred fifty (150) and three hundred (300) nanometers in thickness. The first and second dielectric layers may include a SiO2 material. The step of forming the thicker dielectric portion may include preventing the thicker dielectric from extending over the first well portion or the source. The step of forming the thicker dielectric portion may include extending the thicker dielectric portion along part but not all of the JFET neck region. The method may further include the step of providing a gate structure over the dielectric material, and the steps of providing the dielectric material and the gate structure may include extending the dielectric material and the gate structure over only part of the JFET neck region. The method may also include the step of providing a layer of borophosphosilicate glass at least over the gate structure and the JFET neck region. The volume of semiconductor material may include an N-type epitaxial semiconductor material, and the source may include an N+ material above and adjacent to the well. A P+ material may be implanted to form a body adjacent to the source opposite the well. An N+ substrate material may be provided for a drain at the second end of the volume of semiconductor material, wherein the volume of semiconductor and various components define a channel between the source and the drain provides a first channel.

The method may further include making a second transistor side located at the second side of the volume of semiconductor material and adjacent to the JFET neck region, with the elements described in the foregoing paragraph presenting sections of the components forming a first transistor side. The JFET neck region may present a central JFET neck portion spaced between the well sections of the transistor sides, and the steps of forming the dielectric material and the gate structure may be performed so that the dielectric material and the gate structure do not extend over the central JFET neck portion. Further, a layer of borophosphosilicate glass may be provided at least over the gate structure and the JFET neck region, including over the central JFET neck portion.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of a power MOSFET with a split gate and radiation-hardening against a SEGR effect;

FIG. 2 is a flowchart of operations in an example of a method of making a power MOSFET with a split gate and radiation-hardening against a SEGR effect;

FIG. 3A is a cross-sectional elevation view of the result of an operation in the method of FIG. 2, wherein a volume of semiconductor material is shown on a substrate material, and a P-well material and a P- - material are implanted in the semiconductor material;

FIG. 3B is a cross-sectional elevation view of the result of an operation in the method of FIG. 2, wherein an N+ source material and a P+ body contact material are implanted in the semiconductor material;

FIG. 3C is a cross-sectional elevation view of the result of an operation in the method of FIG. 2, wherein a dielectric material and a polysilicon gate material are deposited on the semiconductor material to create the split gate configuration; and

FIG. 3D is a cross-sectional elevation view of the result of an operation in the method of FIG. 2, wherein electrical terminals are added.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

The next generation of defense and commercial satellites and space launch vehicles as well as the new emerging requirements from the National Air and Space Administration (NASA) for cislunar and lunar manned activities will require increased electrical power for communication, observation, propulsion, and life support systems. The most power efficient architectures require power supply voltages to be increased significantly–ideally to well over one thousand (1000) volts (V). This enables spacecraft designers to reduce both the number, size, and weight of power conversion components (SWAP), which directly translates to significant reductions in both spacecraft size and weight. However, the desired one thousand-plus (1000+) volts operation–with low Rdson–is well beyond what current radiation-hardened silicon (Si) power MOSFET devices can handle. Instead, organizations such as NASA would much prefer to use silicon-carbide (SiC) power devices in next generation spacecraft. Unfortunately, existing commercial-grade one thousand-plus (1000+) volts SiC power devices are not radiation-hardened against single-event effect failures, such as a single-event gate rupture (SEGR) effect, induced by heavy ion bombardment in space.

SEGR events are catastrophic single-event effect failure mechanisms initiated by the passage of heavy ions through the active region of power MOSFETs. In SEGR, an incident heavy ion (e.g., gold) temporarily increases the localized electric field in the dielectric material, or gate oxide, directly above the heavy ion track. The worst case SEGR scenario is a heavy ion strike perpendicular to the silicon surface and through the exact center of a "JFET neck" region. Under positive Vds bias, electrons are drawn down into the N++ substrate, while holes are pushed to the top of the JFET neck region (just under the gate oxide), with a transient image charge of electrons then being formed in the polysilicon gate. Since this is an N-channel device, the gate-source voltage (Vgs) bias already biases the gate negative and the SEGR induced image charge adds to the electric field across the gate oxide over the JFET neck region. The resulting transient (again, on the order of picoseconds) surge in the electric field across this part of the gate oxide–from the positive charge on one side and the negative charge on the other–can then cause the destructive breakdown of the gate oxide directly above the heavy ion track. Heavy ion strikes outside the JFET neck region are less problematic because the generated holes are immediately captured by the grounded N+ source adjacent to the channel. One SEGR mitigation strategy is to simply thicken the gate oxide over the entire active region–both in the device channel and in the JFET neck region–to withstand the transient field from an ion strike. However, increasing the gate oxide uniformly across the device also increases Rdson, and to be effective, the gate oxide thickness would need to be doubled or even tripled.

Examples provide a power MOSFET that is radiation-hardened against a SEGR effect, and a method of making a power MOSFET that is radiation-hardened against a SEGR effect. Broadly, examples provide a radiation-hardened device suitable for applications in environments (e.g., space or military) in which radiation exposure could otherwise significantly degrade the performance or even catastrophically damage a non-hardened device. Further, examples improve the SEGR radiation hardness of power MOSFETS without significantly degrading Rdson. Some examples may include a power MOSFET that has first and second transistor sides that share the JFET neck region, wherein the JFET neck region may be centrally located between the first and second power MOSFETs.

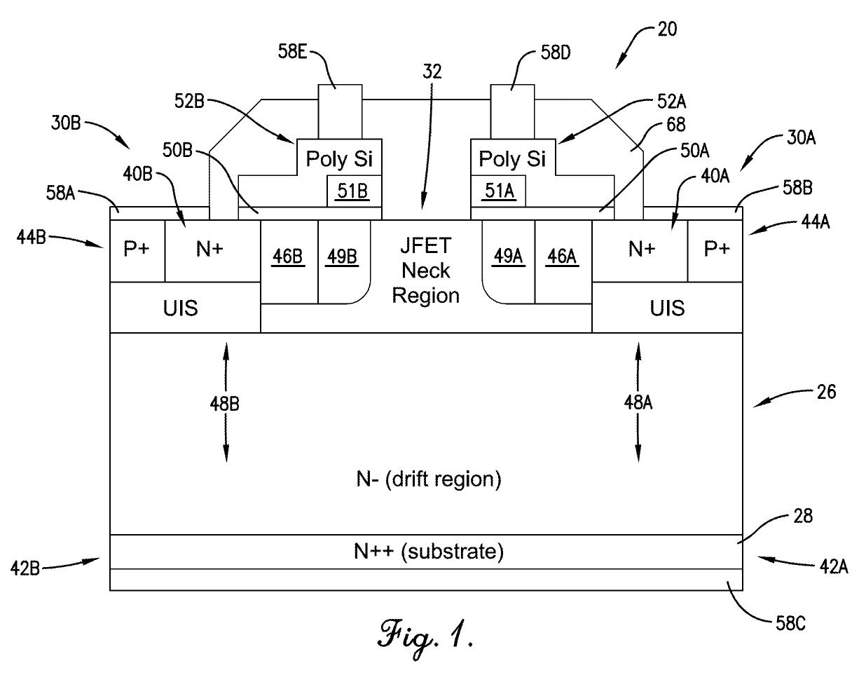

Referring to FIG. 1, an example of a power MOSFET 20 with a split gate and that is radiation-hardened against a SEGR effect is shown. Broadly, the MOSFET 20 may include a volume of semiconductor material 26, a doped substrate material 28, and a JFET neck region 32. The volume of semiconductor material 26 may include a first end, a second end, a first side, and a second side. The volume of semiconductor material 26 may be constructed from or include an N-type epitaxial semiconductor material. The doped substrate material 28 may be located at the second end of the volume of semiconductor material 26. The doped substrate material 28 may be constructed from or include an N+ substrate material. The JFET neck region 32 may be a region of the volume of semiconductor material 26 located at the first end of the volume of semiconductor material 26.. The apparatus 20 may further include a first and second transistor sides 30A, 30B located at the first and second sides of the volume of semiconductor material 26, respectively. The JFET neck region 32 may be centrally located between the first and second transistor sides 30A, 30B. The illustrated MOSFET 20 is consequently a dual channel transistor. Although the apparatus 20 is generally shown and described herein as including the first and second transistor sides 30A, 30B, other examples may include only one transistor side 30A or 30B, with such an alternative example being a single channel MOSFET.

The MOSFET 20 may be a SiC MOSFET, although other suitable semiconductor materials are within the ambit of certain examples. The first and second power transistor sides 30A, 30B may include respective first and second regions or subvolumes of the volume of semiconductor material 26. Thus, the volume of semiconductor material 26 may be a single, physically continuous structure that is shared by the first and second transistor sides 30A, 30B. The first and second transistor sides 30A, 30B may further include respective first and second portions of the doped substrate material 28. Thus, the doped substrate material 28 may be a single, physically continuous structure that is shared by the first and second power transistor sides. The first and second transistor sides 30A, 30B may further include respective first and second instances of various structures and associated materials. Generally, the first and second transistor sides 30A, 30B may be mirror-images or "flipped" versions (i.e., flipped about an imaginary axis through the JFET neck region 32) of each other–i.e., some or all of the respective structures and associated materials may be reversed in order or position on opposite sides of the shared JFET neck region 32. The first and second transistor sides 30A, 30B may otherwise be substantially similar or identical.

Respective first and second instances of the various structures and materials of the first and second transistor sides 30A, 30B may be implanted (using, e.g., an ion implanter), deposited, or otherwise provided using a suitable technique in or on the respective subvolumes of the volume semiconductor material 26. These structures and materials and their sizes and positions may vary, but may generally include the following. Generally speaking the MOSFET 20 includes a source 40, a drain 42, a body contact 44, and a well 46. Because the illustrated example is a dual channel MOSFET, each of these components (the source 40, the drain 42, the body contact 44, and the well 46) are segmented into a pair of sections associated with respective ones of the transistor sides 30A, 30B. First and second source sections 40A, 40B may be constructed from or include an N+ material, and may be located at the first end of the respective subvolumes of volume of semiconductor material 26 and generally opposite first and second drain sections 42A, 42B provided by the respective portions of the N+ substrate 28. First and second body contact sections 44A, 44B may be constructed from or including a P+ material, and may be located adjacent to the respective first and second source sections 40A, 40B. First and second well sections 46A, 46B may be constructed from or include a P+ material, and may be located below and adjacent to the respective first and second source sections 40A, 40B, with each well section 46A, 46B being located at an opposite side of the respective source section 40A, 40B from the respective body contact sections 44A, 44B. First and second channels 48A, 48B may be provided by respective first and second regions of the respective subvolumes of the volume of semiconductor material 26 between the respective first and second source sections 40A, 40B and the respective first and second drain sections 42A, 42B. The majority charge carriers may move and the electrical current may flow through the channels 48A 48B. First and second low-doped regions 49A, 49B (which may comprise a portion of the corresponding well section 46A, 46B) may be constructed from or include a lightly doped P- - material, and may be located between the JFET neck region 32 and the other portion of the respective well sections 46A, 46B.

First and third layers of dielectric material 50A, 50B, or gate oxide (e.g., silicon oxide (SiO2)), may be provided over a portion of respective sides of the JFET neck region 32, over the low-doped well portions 49A, 49B, at least partially over the respective first and second well sections 46A, 46B, and at least partially over the respective first and second source sections 40A, 40B. As seen in FIG. 1, the illustrated example includes no dielectric material over a center portion of the JFET neck region 32 between the first and second transistor sides 30A, 30B. Second and fourth layers of dielectric material 51A, 51B may be provided partially over the respective first and third layers of dielectric material 50A, 50B. The first and third dielectric layers 50A, 50B may be relatively thinner than the second and fourth dielectric layers 51A, 51B. For example, the first and third layers of dielectric material 258 may be between fifty (50) and one hundred (100) nanometers in thickness, and the second and fourth layers of dielectric material 260 may be between one hundred fifty (150) and three hundred (300) nanometers in thickness. The second and fourth dielectric layers 51A, 51B may be deposited and, as desired, patterned so as to be located only over the respective portions of the respective first and third dielectric layers 50A, 50B that are located over the JFET neck region 32, and the respective low-doped well portions 49A, 49B, thereby creating a double layer of dielectric material and improving SEGR hardness. As seen in FIG. 1, the illustrated example MOSFET 20 includes no dielectric material over a center portion of the JFET neck region 32 which is centrally located between the first and second transistor sides 20A, 20B. However, according to certain aspects, either combined dielectric layer (the first and third layers 50A, 50B on the one hand, and the second and fourth layers 51A, 51B on the other) or both combined layers may alternatively extend continuously across the JFET neck region 32 so that there is no “unexposed” semiconductor material along the first end thereof between the well portions 49A, 49B. Furthermore, according to some examples, either combined layer (50 or 51) or both combined layers (50 and 51) may extend continuously between the source sections 40A, 40B. In other words, certain examples contemplate a dielectric material (gate oxide) extending over the JFET neck region 32. Alternative examples may further include the thicker portion of dielectric material (including both illustrated layers) extending continuously over the JFET neck region 32 and, in some examples, between the source sections 40A, 40B.

The lightly-doped P- - material of the first and second low-doped well portions 49A, 49B may be located below the transition region of the double layers of dielectric material to the single layers of dielectric material. First and second gate sections 52A, 52B may be split or separated by the center portion of the JFET neck region 32, and, as a result, the potential for a high SEGR-induced electric field over the JFET neck region 32 is greatly reduced. In more detail, to avoid massively increasing Rdson while still providing SEGR hardening, the second and fourth dielectric layers (also known as thick terraced oxide (TEROX) layers) 51A, 51B may be deposited and patterned over a portion of the thinner first and third layers of dielectric material layer 50A, 50B. The areas along which the layers are combined cooperatively present a thicker portion of the dielectric material. In the process flow, the first and third dielectric layers 50A, 50B may be initially constructed as a single layer extending across the JFET neck region 32, and the third and fourth dielectric layers 51A, 51B may initially be constructed as a single layer extending across the JFET neck region 32, and the center portions of each of these single layers over the JFET neck region 32 may be removed by dry or wet etching or a combination thereof, thereby splitting the dielectric material into two (2) discreet structures, with portions of each of which being defined by two (2) layers to present thicker portions of the dielectric material. It is further noted that the thicker portion of dielectric material (defined in the illustrated example by the combination of dielectric layers 50A and 51A and the dielectric layers 50B and 51B) extends along only part of the low-doped well portions 49A, 49B. In the illustrated example, each of the low-doped well portions 49A, 49B presents a length extending along the first end of the volume of semiconductor material 26, and the thicker dielectric portion may extend along more than half of each length. However, according to certain alternative examples, the thicker dielectric portion may extend along the entire length of each low-doped well portion 49A, 49B. Furthermore, the illustrated MOSFET 20 includes a thicker dielectric portion that does not extend over the outer well portions 46A, 46B (the portions of the each well section adjacent the respective source sections 40A, 40B), nor over the source sections 40A, 40B. As previously noted, the illustrated thicker dielectric portion extends over only part of the JFET neck region 32 (with the centermost portion of the illustrated JFET neck region 32 not being overlain with any dielectric material), although it is within the ambit of some aspects of the example MOSFET for the thicker dielectric portion to extend continuously over the JFET neck region 32 between the lower-doped well portions 49A, 49B.

The first and second gate sections 52A, 52B may be constructed from or include a doped polysilicon material, and may be located over the respective first and second layers 50A, 51A and third and fourth layers 50B, 51B of dielectric material. The doped polysilicon may be constructed from or include a P-type polysilicon material. In the illustrated embodiment (as seen in FIG. 1), no polysilicon is provided over the center portion of the JFET neck region 32 between the first and second power MOSFETs 30A, 30B. Thus, the first and second gate sections 52A, 52B may be located on either side of the JFET neck region 32, thereby creating the "split gate" configuration. In other words, the gate sections 52A, 52B (and the dielectric material) may extend inwardly over only part of the JFET neck region 32 so that the centermost portion of the JFET neck region 32 is devoid of dielectric material or doped polysilicon. However, according to some aspects of the example MOSFET, the dielectric material (including the thicker portion) and the gate may alternatively extend continuously over the JFET neck region so as to present a single continuous gate.

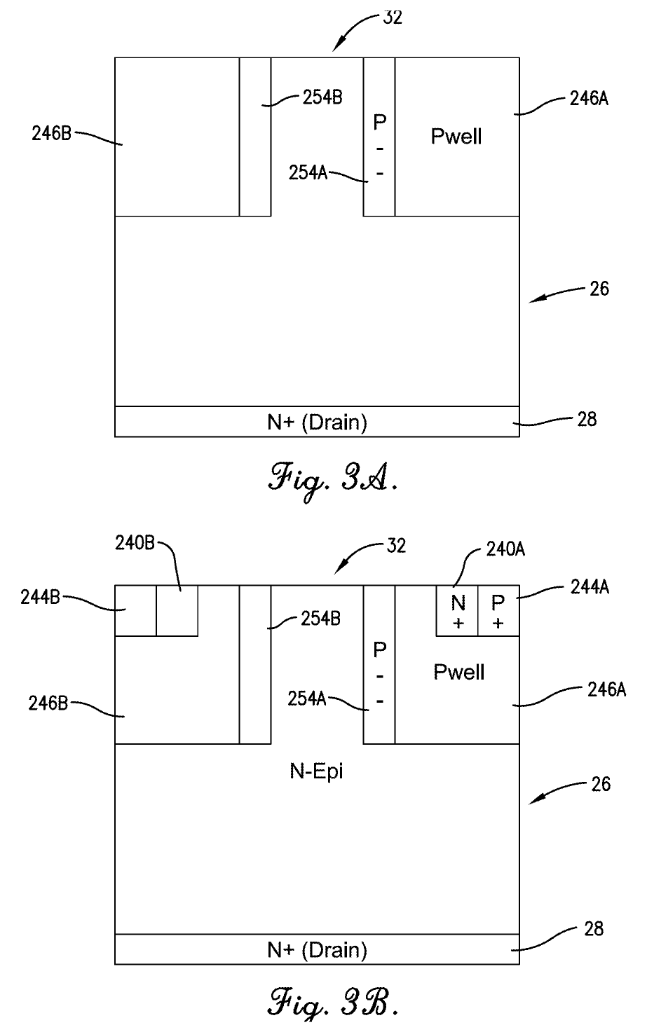

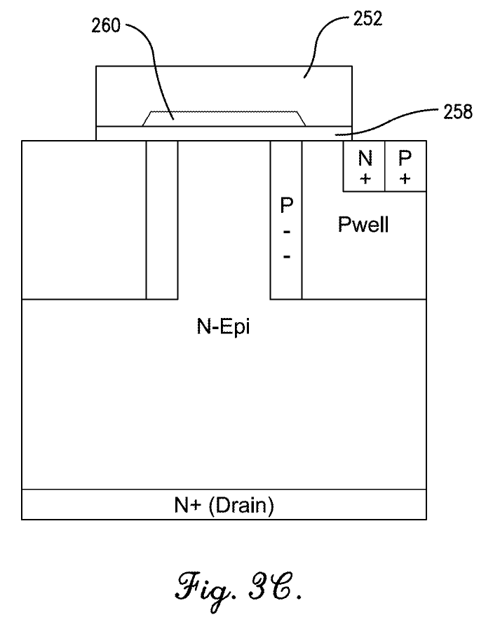

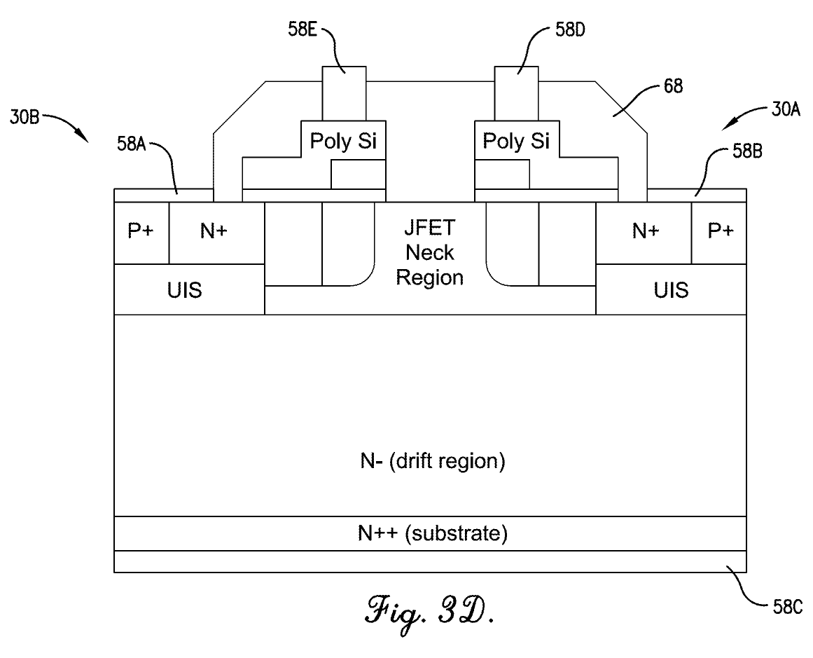

A layer of BPSG 68 may be provided overtop the first and second gate sections 52A, 52B, over the JFET neck region 32, and at least partially over the first and second source sections 40A, 40B. As seen in FIG. 1, the BPSG 68 is provided over the center portion of the JFET neck region 32 which is centrally located between the first and second transistor sides 20A, 20B. Electrical terminals 58A-F may be added to facilitate applying appropriate electrical voltages, as discussed above, as shown in 140 and seen in FIG. 3C. More specifically, first and second electrical terminals 58A, 58B may be added to the respective first and second source sections 40A, 40B, a single third electrical terminal 58C may be added that spans the first and second drain sections 42A, 42B, and fourth and fifth electrical terminals 58D, 58E may be added to the respective first and second gate sections 52A, 52B.

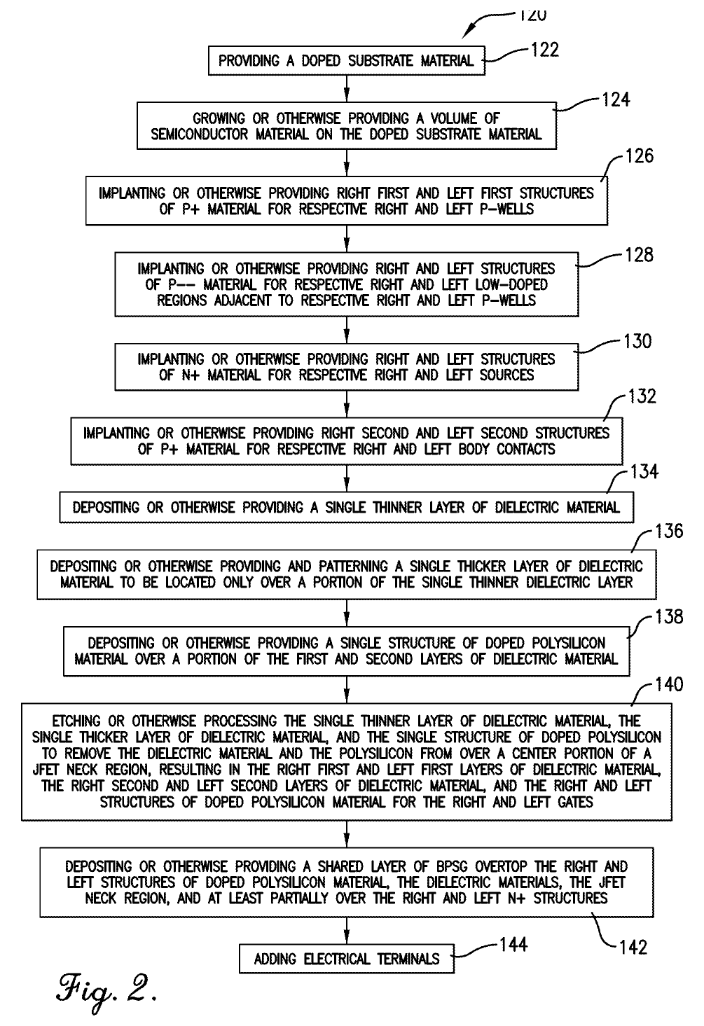

Referring to FIG. 2, an example of a method 120 of making a power MOSFET that is radiation-hardened against SEGR effects may include the following operations. References are also made to FIGS. 3A - D showing the results of certain operations of the method 120, and to FIG. 1 and the example MOSFET 20 described above and which may be made using the method 120. Although the method 120 is described as making the device 20 including the first and second transistor sides 30A, 30B, the MOSFET 20 may be made with only one of the transistor sides 30A or 30B. As discussed above, the first and second transistor sides 30A, 30B may be mirror-images or "flipped" versions of each other, and may otherwise be substantially similar or identical.

The doped substrate material 28 may be provided, as shown in 122 and seen in FIG. 3A. The doped substrate material 28 may be a single, physically continuous structure that is shared by the first and second transistor sides 30A, 30B. Thus, the first and second transistor sides 30A, 30B may include respective first and second portions of the doped substrate material 28. The doped substrate material 28 may be constructed from or include an N+ doped substrate material.

The volume of semiconductor material 26 may be grown or otherwise deposited on the doped substrate material 28, as shown in 124 and seen in FIG. 3A. The volume of semiconductor material 26 may include a first end, a second end, a first side, and a second side. The doped substrate material 28 may be located at the second end of the volume of semiconductor material 26, the first and second transistor sides 30A, 30B may be located at respective first and second sides of the volume of semiconductor material 26, and a region of the volume of semiconductor material 26 located between the first and second transistor sides 30A, 30B may provide the JFET neck region 32. The volume of semiconductor material 26 may be constructed from or include an N-type epitaxial semiconductor material.

The first and second transistor sides MOSFETs 30A, 30B may be simultaneously constructed, as seen in FIGS. 3A - D. The first and second transistor sides 30A, 30B may be formed within a SiC volume of semiconductor material. The first and second transistor sides 30A, 30B may include respective first and second regions or subvolumes of the volume of semiconductor material 26. Thus, the volume of semiconductor material 26 may be a single, physically continuous structure that is shared by the first and second transistor sides 30A, 30B.

The first and second transistor sides 30A, 30B may further include respective first and second instances of various structures and materials. The first and second instances of the various structures and materials may be implanted (using, e.g., an ion implanter), deposited, or otherwise provided using a suitable technique in or on the respective subvolumes of the volume semiconductor material 26. These structures and materials and their sizes and positions may vary but may generally include the following. First and second structures of P+ material 246A, 246B for the respective first and second well sections 46A, 46B may be implanted or otherwise provided in the respective subvolumes at the first end of the volume of semiconductor material 26, as shown in 126 and seen in FIG. 3A. First and second structures of lightly doped P- - material 254A, 254B may be implanted for the respective first and second low-doped well portions 49A, 49B adjacent to the respective first and second well sections 46A, 46B, as shown in 128 and seen in FIG. 3A.

First and second structures of N+ material 240A, 240B for the respective first and second source sections 40A, 40B may be implanted or otherwise provided in the respective subvolumes of the volume of semiconductor material 26 at the first end, over and adjacent to the respective first and second structures of P+ material and generally opposite the first and second drain sections 42A, 42B provided by the respective portions of the doped substrate material 28, as shown in 130 and seen in FIG. 3A. Third and fourth structures of P+ material 244A, 244B for the respective first and second body contact sections 44A, 44B may be implanted or otherwise provided adjacent to the respective first and second source sections 40A, 40B, such that each body contact section 44A, 44B is located on an opposite side of the respective source section 40A, 40B from the respective P-well portions 46A, 46B, as shown in 132 and seen in FIG. 3A. It will be understood that the first and second channels 48A, 48B may be provided by respective first and second regions of the respective subvolumes of the volume of semiconductor material 26 between the respective structures of N+ material 240A, 240B of the first and second source sections 40A, 40B and the doped substrate material 28 of the respective first and second drain sections 42A, 42B. The majority charge carriers may move and the electrical current may flow through the channels 48A 48B.

A single thinner layer of dielectric material 258, or gate oxide (e.g., SiO2), may be deposited or otherwise provided extending across the JFET neck region 32, the first and second low-doped regions 254A, 254B, at least partially over the first and second structures of P+ material 246A, 246B, and at least partially over the first and second structures of N+ material 240A, 240B, as shown in 134 and seen in FIG. 3C. The single thinner layer of dielectric material 258 will become the first and third dielectric layers 50A, 50B, as described below.

A single thicker layer of dielectric material 260 may be deposited or otherwise provided and patterned so as to be located only over a portion of the single thinner dielectric layer 258 that is located over the JFET neck region 32, and the first and second low-doped regions 254A, 254B, thereby creating a double layer (thicker portion) of dielectric material, as shown in 136 and seen in FIG. 3C. The single thinner layer of dielectric material 258 may be relatively thinner than the single thicker of dielectric material 260. For example, the first layer of dielectric material 258 may be between fifty (50) and one hundred (100) nanometers in thickness, and the second layer of dielectric material 260 may be between one hundred fifty (150) and three hundred (300) nanometers in thickness. The single thicker layer of dielectric material 260 will become the second and fourth dielectric layers 51A, 51B, as described below.

A single structure of doped (e.g., P-type) polysilicon material 252 for the first and second gate sections 52A, 52B may be deposited or otherwise provided over the portions of the dielectric material 258, 260, as shown in 138 and seen in FIG. 3C. The single structure of doped polysilicon material 252 will become the first and second structures of doped polysilicon for the first and second gate sections 52A, 52B, as described below.

The single thinner layer of dielectric material 258, single thicker layer of dielectric material 260, and the single structure of doped polysilicon 252 may be etched (dry, wet, or a combination thereof) or otherwise processed to remove the portion of the dielectric material and the polysilicon that is over a center portion of the JFET neck region, as shown in 140 and seen in FIG. 3D. This splits the original single structures and results in the first and second layers of dielectric material 50A, 50B, the third and fourth layers of dielectric material 60A, 60B, and the first and second structures of doped polysilicon material for the first and second gate sections 52A, 52B.

A single layer of BPSG 68 may be provided overtop the first and second structures of doped polysilicon material 252A, 252B, the dielectric materials 58A, 58B, 60A, 60B, the JFET neck region 32, and at least partially over the first and second N+ structures 240A, 240B of the first and second source sections 40A, 40B, as shown in 142. As seen in FIG. 1, the BPSG 68 may be provided over the center portion of the JFET neck region 32 which is centrally located between the first and second power MOSFETs 20A, 20B.

Electrical terminals 58A-F may be added to facilitate applying appropriate electrical voltages, as discussed above, as shown in 140 and seen in FIG. 3C. More specifically, first and second electrical terminals 58A, 58B, may be added to the respective first and second source sections 40A, 40B, a single third electrical terminal 58C may be added that spans the first and second drain sections 42A, 42B, and fourth and fifth electrical terminals 58D, 58E may be added to the respective first and second gate sections 52A, 52B. According to certain aspects, terminals for common components (or even other components) may be shorted as desired.

Additional processing may occur as desired.

Although described herein with regard or in relation to one or more particular kinds of electronic devices (e.g., metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, unless otherwise specified or unless one with ordinary skill in the art would understand otherwise, the gate material may include polysilicon, a metal or alloy of metals, or other suitable material; the gate oxide or dielectric may include silicon dioxide, aluminum oxide, hafnium dioxide, silicon nitride, or other suitable material; and the semiconductor material may include silicon carbide, silicon gallium nitride, zinc oxide, or other suitable material.

It will be appreciated that the sides of the illustrated volume of semiconductor material are defined herein merely as an example, and may in various examples represent only a portion of semiconductor material relative to the illustrated device. In practice, the volume of semiconductor material may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be FETs (which may be similarly or alternatively constructed to the illustrated MOSFET 20) or may be entirely different devices providing different operations or functions than the illustrated MOSFET 20. In other words, in practice, the illustrated MOSFET 20 may be just one of numerous devices spaced laterally and transversely within a single, integrally formed component, such as a wafer or integrated circuit (not shown).

Additionally, in general, unless otherwise specified or unless one with ordinary skill in the art would understand otherwise, doping concentrations for contact implants may be approximately between ten to the power of eighteen (10^18) and ten to the power of twenty two (10^22); doping concentrations for channel and threshold forming implants may be approximately between ten to the power of sixteen (10^16) and ten to the power of seventeen (10^17); doping concentrations for shielding implants may be approximately between ten to the power of seventeen (10^17) and ten to the power of nineteen (10^19); and doping concentrations for conductivity improvement implants (e.g., N- doping in the junction field-effect transistor neck region of a metal oxide semiconductor field-effect transistor) may be approximately between ten to the power of sixteen (10^16) and ten to the power of seventeen (10^17). Relatedly, a structure or region may contain two or more different doping doses. For example, one with ordinary skill in the art will recognize that some P-wells may contain a lower dose P-well portion and a higher dose unclamped inductive switching portion.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A metal oxide semiconductor field-effect transistor (MOSFET) comprising:
a volume of semiconductor material including a first end, a second end, a first side, and a second side;
a junction field-effect transistor (JFET) neck region located between the first side and the second side of the volume of semiconductor material;
a source;
a well located between the source and the JFET neck region,
the well including a first well portion and a second well portion,
the second well portion being located between the first well portion and the JFET neck region and having a lower dopant concentration than the first well portion; and
a dielectric material overlying the first well portion, at least part of the second well portion, and at least part of the source,
the dielectric material presenting a thicker dielectric portion located over the second well portion.

2. The MOSFET of claim 1,
the dielectric material including a first dielectric layer overlying the first end of the volume of semiconductor material along the first well portion, at least part of the second well portion, and at least part of the source,
the dielectric material including a second dielectric layer overlying the first dielectric layer along at least part of the second well portion such that the first and second dielectric layers cooperatively present the thicker dielectric portion,
the first layer of dielectric material being between fifty (50) and one hundred (100) nanometers in thickness,
the second layer of dielectric material being between one hundred fifty (150) and three hundred (300) nanometers in thickness.

3. The MOSFET of claim 1,
the thicker dielectric portion extending along part but not all of the second well portion.

4. The MOSFET of claim 3,
the second well portion presenting a length defined along the first end of the volume of semiconductor material,
the thicker dielectric portion extending along more than half the length of the second well portion.

5. The MOSFET of claim 3,
the thicker dielectric portion extending along part but not all of the JFET neck region.

6. The MOSFET of claim 5,
the thicker dielectric portion not extending over the first well portion or the source.

7. The MOSFET of claim 3,
the well including spaced apart well sections, each including respective first and second well portions,
the JFET neck region being located between the second well portions of the spaced apart well sections,
the source including spaced apart source sections, each being located between one of the well sections and a respective one of the sides of the volume of semiconductor material,
the dielectric material overlying each of the first well portions, at least part of each of the second well portions, and at least part of each of the source sections,
the thicker dielectric portion being located along part but not all of each of the second well portions.

8. The MOSFET of claim 7,
the JFET neck region presenting a central JFET neck portion spaced between the second well portions of the spaced apart well sections,
the thicker dielectric portion extending over the JFET neck region adjacent each of the second well portions but not over the central JFET neck portion.

9. The MOSFET of claim 8, comprising:
a gate structure located over the dielectric material.

10. The MOSFET of claim 9,
the dielectric material and the gate structure not extending over the central JFET neck portion.

11. The MOSFET of claim 10, comprising:
a layer of borophosphosilicate glass at least over the gate structure and the JFET neck region, including over the central JFET neck portion.

12. The MOSFET of claim 1, comprising:
a gate structure located over the dielectric material.

13. The MOSFET of claim 12,
the dielectric material and the gate structure extending over only part of the JFET neck region.

14. The MOSFET of claim 13, comprising:
a layer of borophosphosilicate glass at least over the gate structure and the JFET neck region.

15. A method of making a metal oxide semiconductor field-effect transistor (MOSFET) comprising:
growing a volume of semiconductor material including a first end, a second end, a first side, and a second side, and including a junction field-effect transistor (JFET) neck region located between the first side and the second sides;
providing a source;
providing a well between the source and the JFET neck region,
the step of providing the well including –
providing a first well portion adjacent the source, and
providing a second well portion, having a lower dopant concentration than the first well portion, between the first well portion and the JFET neck region; and
providing a dielectric material over the first well portion, at least part of the second well portion, and at least part of the source,
the step of providing the dielectric material including forming the dielectric material to have a thicker portion over the second well portion.

16. The method of claim 15,
the step of providing the dielectric material including forming a first dielectric layer and a relatively thicker second dielectric layer,
the step of forming the first dielectric layer including extending the first dielectric layer over the first end of the volume of semiconductor material along the first well portion, at least part of the second well portion, and at least part of the source,
the step of forming the second dielectric layer including extending the second dielectric layer over the first dielectric layer along at least part of the second well portion such that the first and second dielectric layers cooperatively present the thicker dielectric portion,
the step of forming the first and second dielectric layers being performed such that the first dielectric layer is between fifty (50) and one hundred (100) nanometers in thickness, and the second dielectric layer is between one hundred fifty (150) and three hundred (300) nanometers in thickness.

17. The method of claim 15,
the step of forming the thicker dielectric portion including preventing the thicker dielectric from extending over the first well portion or the source.

18. The method of claim 17,
the step of forming the thicker dielectric portion including extending the thicker dielectric portion along part but not all of the JFET neck region.

19. The method of claim 18, comprising:
providing a gate structure over the dielectric material,
the steps of providing the dielectric material and the gate structure including extending the dielectric material and the gate structure over only part of the JFET neck region.

20. The method of claim 19, comprising:
providing a layer of borophosphosilicate glass at least over the gate structure and the JFET neck region.
